(19) United States
(12) Patent Application Publication
(10) Pub. No.: US 2018/0197897 A1
(43) Pub. Date: Jul. 12, 2018

(54) ARRAY SUBSTRATE AND METHOD FOR FABRICATING THE SAME, DISPLAY DEVICE

(71) Applicants: BOE TECHNOLOGY GROUP CO., LTD., Beijing (CN); CHENGDU BOE OPTOELECTRONICS TECHNOLOGY CO., LTD., Chengdu, Sichuan Province (CN)

(72) Inventors: Yanxia XIN, Beijing (CN); Yuqing YANG, Beijing (CN); Xiaofei YANG, Beijing (CN)

(73) Assignees: BOE TECHNOLOGY GROUP CO., LTD., Beijing (CN); CHENGDU BOE OPTOELECTRONICS TECHNOLOGY CO., LTD., Chengdu, Sichuan Province (CN); CHENGDU BOE OPTOELECTRONICS TECHNOLOGY CO., LTD., Chengdu, Sichuan Province (CN)

(21) Appl. No.: 15/127,771

(22) PCT Filed: Aug. 3, 2015
(86) PCT No.: PCT/CN2015/085907

§ 371 Date: Sep. 20, 2016

(30) Foreign Application Priority Data
Apr. 14, 2015 (CN) 201510175829.X

(51) Int. Cl. H01L 27/12; H01L 21/77; H01L 21/28

(52) U.S. Cl. CPC H01L 27/1255; H01L 2021/775; H01L 21/28; H01L 21/77

(57) ABSTRACT

An array substrate and a method for fabricating the same, and a display device are disclosed. The array substrate comprises: a thin film transistor comprising an active region, a source/drain and a gate; a shading part arranged below the active region and made from an electrically conductive material; and a storage capacitor comprising a first plate and a second plate which are spaced apart and arranged oppositely. The first plate is arranged in a same layer as the shading part, and the second plate is arranged in a same layer as any one of the active region, the source/drain and the gate.

### RELATED APPLICATIONS

The present application claims the benefit of Chinese Patent Application No. 201510175829.X, filed on Apr. 14, 2015, the entire disclosure of which is incorporated herein by reference.

### TECHNICAL FIELD

The present invention relates to the field of display technology, and particularly to an array substrate and a method for fabricating the same, a display device.

### BACKGROUND

In a GOA array substrate, a gate driver circuit for driving gate lines is directly formed at a peripheral region of the array substrate. However, the gate driver circuit generally consists of several shifting registers which are connected in cascade. FIG. 1 shows a circuit structure of a common shifting register. As can be seen, it comprises a plurality of storage capacitors C.

Plates of the storage capacitor C are generally designed in the following manners. In a first manner, a polycrystalline silicon layer and a gate layer act as two plates of the storage capacitor C respectively. In a second manner, a polycrystalline silicon layer and a data line layer act as two plates of the storage capacitor C respectively. In the first and second manner, due to high resistance of polycrystalline silicon, it is required to add a mask plate for heavily doping the polycrystalline silicon to decrease resistance. In addition, the heavily doped polycrystalline silicon still has a resistance which is significantly larger than that of a metal, so that it is further required to increase the area of plates of the storage capacitor. In a third manner, a gate layer and a data line layer act as two plates of the storage capacitor C respectively. The third manner shown in FIG. 2 is generally adopted, so that there is no need to add a mask plate.

As shown in FIG. 2, a thin film transistor in the gate driver circuit comprises an active region 4′, a gate 2′, and a source/drain 3′. The storage capacitor C consists of two plates 21′, 31′, the first plate 21′ is arranged in a same layer as the gate 2′, and the second plate 31′ is arranged in a same layer as the source/drain 3′ (i.e., a data line). In practice, the first and second plate 21′, 31′ are further connected to other structures. For example, the first plate 21′ may be connected to a gate of a thin film transistor, and the second plate 31′ may be connected to ground. The array substrate further comprises known structures, such as a base plate 9′, a buffer layer 5′, a gate insulating layer 6′, an interlayer insulating layer (ILD) 7′, which are stacked sequentially and are not described in detail herein. In the design shown in FIG. 2, since the ILD 7′ between a layer in which the gate is arranged and a layer in which the source/drain (data line) is arranged is relatively thick, it is required that plates of the storage capacitor C have large an area.

Based on the above plate design, the storage capacitor C has a decreased capacitance and thus is not accepted. Especially with the development of a display device with narrow bezel, the gate driver circuit has a decreased area, and the storage capacitor also has a decreased area, so that the capacitance is further decreased. Therefore, there is a need for an improved design for the storage capacitor in the art.

### SUMMARY

In view of the problem of insufficient area of plates and small capacitance in the existing array substrate, the present invention provides an array substrate and a method for fabricating the same, a display device, which can increase capacitance of the storage capacitor without increasing the area.

To this end, the following technical solutions are adopted in embodiments of the present invention.

In a first aspect, it is provided an array substrate, comprising:

a thin film transistor, comprising an active region, a source/drain and a gate;

a shading part which is arranged below the active region and made from an electrically conductive material; and

a storage capacitor, comprising a first plate and a second plate which are spaced apart and arranged oppositely,

wherein the first plate is arranged in a same layer as the shading part, and the second plate is arranged in a same layer as any one of the active region, the source/drain and the gate.

In an exemplary embodiment, the second plate is arranged in a same layer as the source/drain or the gate.

In an exemplary embodiment, the storage capacitor further comprises: a third plate electrically connected with the first plate, wherein the second plate is arranged between the first plate and the third plate, and the second plate and the third plate are arranged in a same layer as two layers among the gate, the source/drain and the active region respectively.

In an exemplary embodiment, the shading part, a buffer layer, the active region, a gate insulating layer, the gate, an interlayer insulating layer and the source/drain are arranged sequentially in a direction away from a base plate of the array substrate; the second plate is arranged in a same layer as the gate; and the third plate is arranged in a same layer as the source/drain.

In an exemplary embodiment, at least one insulating layer is arranged between a layer in which the shading part is arranged and a layer in which the second plate is arranged; and the at least one insulating layer has a thickness t1 over the first plate and a thickness t2 over the shading part, wherein 0≤t1≤t2.

In an exemplary embodiment, the at least one insulating layer is a buffer layer covering the shading part; and the active region is arranged over the buffer layer.

In an exemplary embodiment, the third plate is electrically connected with the first plate via a via hole which runs through the buffer layer, the gate insulating layer and the interlayer insulating layer.

In an exemplary embodiment, the active region is made from low temperature polycrystalline silicon.

In an exemplary embodiment, the array substrate comprises a gate driver circuit at a peripheral region, and the storage capacitor is a storage capacitor in the gate driver circuit.

In a second aspect, it is provided a display device, comprising:

the above described array substrate.

In a third aspect, it is provided a method for fabricating an array substrate. The array substrate comprises: a thin film transistor, comprising an active region, a source/drain and a gate; a shading part which is arranged below the active region and made from an electrically conductive material; and a storage capacitor, comprising a first plate and a second plate which are spaced apart and arranged oppositely, wherein the first plate is arranged in a same layer as the shading part, and the second plate is arranged in a same layer as any one of the active region, the source/drain and the gate. The method comprises steps of:

S1, forming a pattern comprising the first plate and the shading part by a first patterning process; and

S2, forming a pattern of the second plate by a second patterning process, and simultaneously forming a pattern of any of the active region, the source/drain and the gate.

In an exemplary embodiment, after the step S1 and prior to the step S2, the method further comprises:

step S102, forming a buffer layer on the pattern comprising the first plate and the shading part.

In an exemplary embodiment, after the step S102, the method further comprises:

step 103, on the base plate from the step S102, forming the active region 4 by a third patterning process.

In an exemplary embodiment, after the step S103, the method further comprises:

step S104, on the base plate from the step S103, thinning the buffer layer at a region other than a region to which the shading part corresponds by etching.

In an exemplary embodiment, after the step S102, the method further comprises:

step S104′, on the base plate from the step S102, forming the active region 4 by a third patterning process, and simultaneously thinning the buffer layer at a region other than a region to which the shading part corresponds.

In an exemplary embodiment, after the step S104 or step S104′, the method further comprises:

step S105, on the base plate from the step S104 or step S104′, forming a gate over the active region and a second plate which is arranged oppositely to the first plate by a fourth patterning process.

In an exemplary embodiment, after the step S105, the method further comprises:

step S106, forming an interlayer insulating layer on the base plate from the step S105; forming a first via hole which runs through the interlayer insulating layer and the gate insulating layer and a second via hole which runs through the interlayer insulating layer, the gate insulating layer and the buffer lay, by a fifth patterning processor; and forming a source/drain which is electrically connected with the active region through the first via hole and a third plate which is electrically connected with the first plate through the second via hole, by a sixth patterning process.

In this context, the term “arranged in a same layer” indicates that two structures in question are made from a same material layer by a patterning process. These two structures lies in a same layer in term of stacking relationship, but do not necessarily have a same distance from the base plate.

In the array substrate of an embodiment of the present invention, the first plate and the shading part of the storage capacitor are arranged in a same layer. As a result, a layer is added in which plates is arranged, so that the total area of plates is increased and thus capacitance of the storage capacitor is increased, without increasing the projection area of the storage capacitor. In addition, the shading part is an existing structure in the array substrate, and the first plate of the storage capacitor is formed at a same time as the shading part. Thus, there is no need for a new step for forming the first plate, and the process does not become complicated.

### BRIEF DESCRIPTION OF THE DRAWINGS

FIG. 1 is a circuit diagram for a known shifting register;

FIG. 2 is a partially cross-sectional view for a known array substrate;

FIG. 3 is a partially cross-sectional view for an array substrate in an embodiment of the present invention;

FIG. 4 is a partially cross-sectional view for an array substrate in an embodiment of the present invention in which an active region has been formed;

FIG. 5 is a partially cross-sectional view for an array substrate in an embodiment of the present invention in which a buffer layer has been thinned;

FIG. 6 is a partially cross-sectional view for an array substrate in an embodiment of the present invention in which an interlayer insulating layer has been formed; and

FIG. 7 is a flow chart for a method for fabricating an array substrate in an embodiment of the present invention.

### DETAILED DESCRIPTION OF EMBODIMENTS

The technical solutions in embodiments of the present invention will be described clearly and completely with reference to the drawings in the embodiments of the present invention.

Reference numerals: 21′, 11 first plate; 31′, 21 second plate; 31, third plate; 1, shading part; 2′, 2 gate; 3′, 3 source/drain; 4′, 4 active region; 5′, 5 buffer layer; 6′, 6 gate insulating layer; 7′, 7 interlayer insulating layer; 9′, 9 base plate; C storage capacitor.

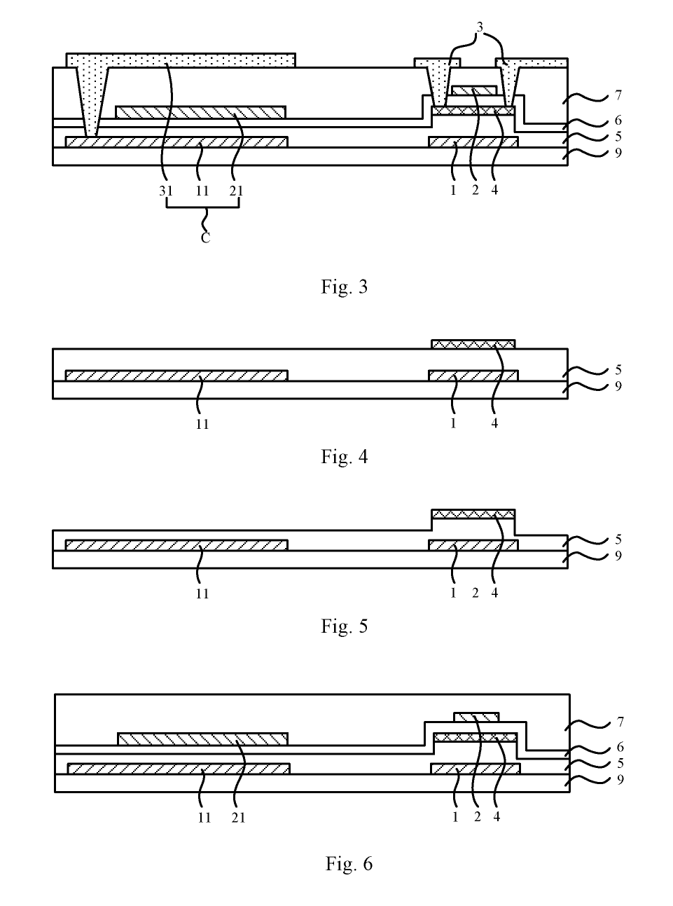

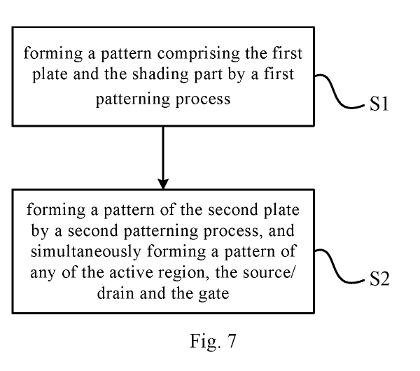

As shown in FIGS. 3-6, an embodiment of the present invention provides an array substrate. the array substrate comprises a thin film transistor, which comprises an active region 4, a source/drain 3, and a gate 2. The array substrate further comprises a storage capacitor C, which comprises a first plate 11 and a second plate 21 which are spaced apart and arranged oppositely.

In particular, the array substrate is an array substrate for use in a display device. The array substrate comprises circuits for realizing different functions (e.g. a gate driver circuit, a pixel circuit), and these circuits comprise thin film transistors and storage capacitors C.

In an exemplary embodiment, the array substrate of the present embodiment comprises a gate driver circuit at a peripheral region. The storage capacitor C in the present embodiment also indicates that a storage capacitor C in the gate driver circuit.

The reasons follow. The storage capacitors in the pixel circuits for driving pixel in the display region generally are acceptable, while in the gate driver circuit for driving gate lines, the storage capacitors C are generally required to have large capacitance. Therefore, the present embodiment is directed to storage capacitors C in the gate driver circuit. Of course, the storage capacitors C in the present embodiment can also be storage capacitors in other circuits like pixel circuits.

In the present embodiment, the array substrate further comprises a shading part 1 which is at least arranged below the active region 4 and made from an electrically conductive material. The first plate 11 of the storage capacitor C and the shading part 1 are arranged in a same layer, and the second plate 21 is arranged in a same layer as any one of the active region 4, the source/drain 3, and the gate 2.

The term “arranged in a same layer” indicates that two structures in question are made from a same material layer by a patterning process. These two structures lies in a same layer in term of stacking relationship, but do not necessarily have a same distance from a base plate 9.

In an existing array substrate, the shading part 1 made from an opaque metal like Ti is arranged below the active region 4, to prevent the light from a backlight from impinging onto the active region 4 of the thin film transistor. In the present embodiment, the first plate 11 is added and arranged in a same layer as the shading part 1. Besides, the first plate 11 is used as a portion of the storage capacitor C. A layer is added for possibly accommodating the plate in the storage capacitor C. In other words, the number of plates in the storage capacitor C is increased. As a result, in case the projection area of the storage capacitor C is constant, the total area of the plate is increased and thus the capacitance is increased.

In an exemplary embodiment, the second plate 21 is arranged in a same layer as the source/drain 3 or the gate 2.

Namely, in an exemplary embodiment the second plate 21 of the storage capacitor C is not arranged in a same layer as the active region 4, but arranged in a same layer as the source/drain 3 or the gate 2. This is because the plate in a same layer as the active region 4 would inevitably made from a semiconductor material of high resistance which makes it difficult to improve properties of the storage capacitor C.

In an exemplary embodiment, the active region 4 is made from low temperature polycrystalline silicon (LTPS).

In other words, in an exemplary embodiment low temperature polycrystalline silicon is used as a material for the active region 4 of thin film transistor. This is because generally low temperature polycrystalline silicon is sensitive to light. In case it is applied in the active region 4, the shading part 1 is generally required.

Of course, if the active region 4 is made from other semiconductor materials, the above mentioned shading part 1 can also be used.

In an exemplary embodiment, the storage capacitor C further comprises a third plate 31 which is electrically connected with the first plate 11 through a via hole. The second plate 21 is arranged between the first plate 11 and the third plate 31. The second plate 21 and the third plate 31 are arranged in a same layer as two layers among the gate 2, the source/drain 3, and the active region 4 respectively.

In other words, as shown in FIG. 3, plates in different layers can be connected together to constitute a plate of the storage capacitor. As a result, in case the projection area of the storage capacitor C is kept constant, the total area of the plate is further increased (i.e., the number of plates is increased), and the capacitance is increased. The above mentioned shading part 1 and first plate 11 are generally directly arranged on the base plate 9, and there are no layer structure which lies below the shading part 1 and first plate 11. Therefore, it is preferred to connect the first plate 11 with the third plate 31, and to arrange the second plate 21 between the first plate 11 with the third plate 31.

In an exemplary embodiment, the shading part 1, a buffer layer 5, the active region 4, a gate insulating layer 6, the gate 2, an interlayer insulating layer 7 and the source/drain 3 are arranged sequentially in a direction away from the base plate 9 of the array substrate. The second plate 21 and the gate 2 are arranged in a same layer. The third plate 31 and the source/drain 3 are arranged in a same layer.

In other words, in an exemplary embodiment the array substrate has a structure shown in FIG. 3. The thin film transistor is of a top gate type, and a layer in which the source/drain 3 is arranged is arranged over a layer in which the gate 2 is arranged. Thereby, the second plate 21 and the gate 2 are arranged in a same layer, act as a plate of the storage capacitor C, and is sandwiched between the first plate 11 and the third plate 31. The third plate 31 is arranged in a same layer as the source/drain 3, and is electrically connected with the first plate 11 through a via hole, so as to together constitute the other plate of the storage capacitor C.

This is because although theoretically there are various positional relationships among the active region 4, the source/drain 3 and the gate 2 in the thin film transistor, the case as shown above is optimal in term of process difficulty, reliability, technology maturity. In case it is not desired to arrange the plate in a same layer as the active region 4 so as to reduce resistance, the second plate 21 and the third plate 31 are inevitably arranged in the above manner.

Of course, it should be appreciated that the storage capacitor C is not limited to this form. For example, it is also possible to arrange a plate in a same layer as the active region 4 to act as a portion of the storage capacitor C. Alternatively, the gate 2 and the source/drain 3 can be exchanged in position.

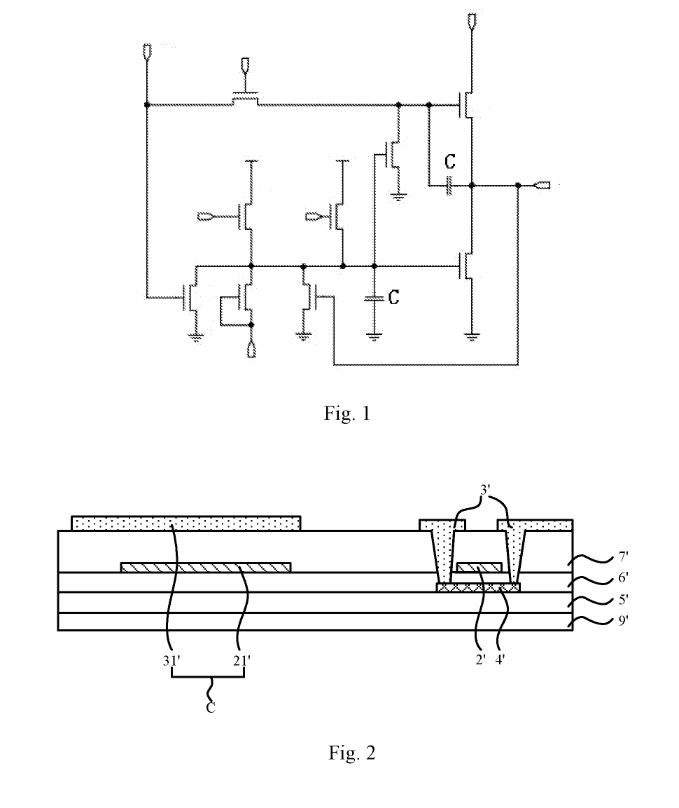

In addition, it should be appreciated that two plates of the storage capacitor C should be electrically connected with other structures in the array substrate, so as to form a portion of the circuit. For example, as for the storage capacitor C in the upper portion of FIG. 1, the third plate 31 (i.e., one of the plates of the storage capacitor C) can be connected with a drain of a thin film transistor (of course further connected with a source of another thin film transistor), while the second plate 21 can be connected with the gate 2 of the thin film transistor. Drawings schematically illustrate layer relationships among plates of the storage capacitor C, and the connection between plates and other structures are not shown.

Of course, depending on the circuit configuration, two plates of the storage capacitor C are connected in various manners. In addition, in practical applications, other layers or structures like a planarization layer, a protection layer may be present over the structure shown in FIG. 3. These belong to common design or structure in the art and thus are not described in detail herein.

In an exemplary embodiment, at least one insulating layer is arranged between a layer in which the shading part 1 is arranged and a layer in which the second plate 21 is arranged. An insulating layer is arranged over the first plate 11. Alternatively, the insulating layer over the first plate 11 has a thickness smaller than over the shading part 1. Namely, the insulating layer has a thickness t1 over the first plate and a thickness t2 over the shading part, and 0≤t1≤t2.

In an exemplary embodiment, the above insulating layer is the buffer layer 5 covering the shading part 1, and the active region 4 is arranged on the buffer layer 5.

Apparently, the smaller the distance between the first plate 11 and the second plate 21, the larger the capacitance. A plurality of insulating layers are arranged between a layer in which the first plate 11 is arranged (i.e., a layer in which the shading part 1 is arranged) and a layer in which the second plate 21 is arranged (by taking a layer in which the gate 2 is arranged as an example). To this end, by thinning or removing one or more of these insulating layers at a position corresponding to the first plate 11, it is possible to decrease the distance between the first plate 11 and the second plate 21.

In particular, the shading part 1 (i.e., a layer in which the first plate 11 is arranged) is generally directly arranged on the base plate 9, and is covered by the buffer layer 5, while the active region 4 is arranged on the buffer layer 5. Therefore, the buffer layer 5 can be taken as the insulating layer and completely removed or thinned at a position over the first plate 11, while the buffer layer 5 over the shading part 1 is kept intact. The reason for which the buffer layer 5 is taken as the insulating layer lies in that the buffer layer 5 primarily functions to enhance adhesion between the active region 4 of a semiconductor material and the base plate 9. Therefore, it is only required for the buffer layer 5 to be present at the active region 4. After the active region 4 is formed, the buffer layer 5 can directly be thinned or removed by etching at a position where it is not covered by the active region 4. In this way, there is no need for an additional exposure step, and the process is simple.

Of course, the insulating layer between other plates of the storage capacitor C can also be partially thinned. For example, the interlayer insulating layer 7 between the second plate 21 and the third plate 31 can be thinned, thus increasing the capacitance between the second plate 21 and the third plate 31. However, such thinning requires an separate exposure step (because the interlayer insulating layer 7 at the gate 2 can not be thinned) to control a shape of the interlayer insulating layer 7, and the process is complicated.

An embodiment of the present invention provides a method for fabricating the above array substrate, which comprises steps of:

S1, forming a pattern comprising the first plate 11 and the shading part 1 by a patterning process; and

S2, forming a pattern of the second plate 21, and simultaneously forming a pattern of any one of the active region 4, the source/drain 3 and the gate 2 by a patterning process.

In particular, by taking the array substrate shown in FIG. 3 as an example, the fabricating method is described in details. The method for fabricating the array substrate comprises the following step S101-S106.

S101, the shading part 1 and the first plate 11 are formed on the base plate 9 simultaneously by a patterning process.

The patterning process is a photolithography process, which comprises steps of forming a material layer, applying photoresist, exposing, developing, etching, peeling off photoresist, or the like.

The shading part 1 and the first plate 11 are formed simultaneously from a same material layer by over-etching, and the material is an opaque metal like Ti.

S102, the buffer layer 5 is formed on the base plate 9 from the previous step.

The buffer layer 5 primarily functions to enhance adhesion between the semiconductor material and the base plate 9 (usually glass).

S103, the active region 4 is formed on the base plate 9 from the previous step by a patterning process, and the structure shown in FIG. 4 is obtained.

In an exemplary embodiment the active region 4 is made from low temperature polycrystalline silicon. The low temperature polycrystalline silicon can be formed from amorphous silicon by laser annealing, and the process is not described in detail herein.

S104, etching is performed on the buffer layer 5 on the base plate 9 from the previous step. The buffer layer 5 is locally thinned, and the structure shown in FIG. 5 is obtained.

The exposed buffer layer 5 is removed partially by etching. Namely, the buffer layer 5 is partially thinned at a region other than the region to which the shading part 1 corresponds. The pattern of the active region 4 is used as a mask during etching in this step, and there is no need for an additional mask.

In an exemplary embodiment, in the patterning process for forming the active region 4 in the step S103, the buffer layer 5 is locally thinned by over-etching during forming the active region 4. In other words, the above steps S103 and 104 can be combined into a single step S104′, in which the active region 4 is formed and the buffer layer 5 is partially thinned simultaneously.

S105, the gate insulating layer 6 is formed on the base plate 9 from the previous step, and then the gate 2 and the second plate 21 are formed by a patterning process. The structure shown in FIG. 6 is obtained.

For example, the gate insulating layer 6 covering the active region 4 is formed by blanket deposition. Then, the gate 2 and the second plate 21 are formed simultaneously. The gate 2 is arranged over the active region 4, and the second plate 21 and the first plate 11 are arranged oppositely.

S106, the interlayer insulating layer 7 is formed on the base plate 9 from the previous step, then a via hole which runs through the interlayer insulating layer 7, the gate insulating layer 6, the buffer layer 5 or the like is formed, and the third plate 31 and the source/drain 3 is formed by a patterning process, so that the array substrate shown in FIG. 3 is obtained.

As shown in FIG. 3, by one patterning process, a first via hole which runs through the interlayer insulating layer 7 and the gate insulating layer 6 is formed over the active region 4, and a second via hole which runs through the interlayer insulating layer 7, the gate insulating layer 6 and the buffer layer 5 is formed simultaneously in the region of the storage capacitor. The source/drain 3 is electrically connected with the active region 4 through the first via hole, and the third plate 31 is electrically connected with the first plate 11 through the second via hole. As can be seen, the third plate 31 (and the second via hole) is formed at a same time as the source/drain 3 (and the first via hole), [symbol] and there is no need for an additional mask process.

In other words, the interlayer insulating layer 7 covering the gate 2 and the second plate 21 is formed, the via holes which are electrically connected with the active region 4, the first plate 11, the second plate 21 or the like are formed in respective insulating layer, and then the third plate 31 and the source/drain 3 are formed. The third plate 31 is arranged opposite to the second plate 21, and is electrically connected with the first plate 11 through the via hole. The source and the drain in the source/drain 3 are connected to two sides of the active region 4 respectively, and thus a thin film transistor is formed.

Of course, in a practical array substrate, plates of the storage capacitor C, as well as the source/drain 3 and the gate 2 of the thin film transistor are connected to other structures or signal lines. The connection manner depends on the specific circuit, and thus is not described in detail herein.

An embodiment of the present invention provides a display device, which comprises any one of the array substrate as described above.

In particular, in an exemplary embodiment the display device is a liquid crystal display device, since a backlight is applied in such a liquid crystal display device in which the shading part as described above is arranged.

Of course, the display device can be any product or component with a display function, such as a liquid crystal panel, an electronic paper, an OLED panel, a liquid crystal TV, a liquid crystal monitor, a digital photo frame, a mobile phone, or a tablet.

Apparently, the skilled person in the art can make various modifications and variations to the present invention without departing from the spirit and the scope of the present invention. In this way, provided that these modifications and variations of the present invention belong to the scopes of the claims of the present invention and the equivalent technologies thereof, the present invention also intends to encompass these modifications and variations.

1. An array substrate, comprising:
a thin film transistor comprising an active region, a source/drain and a gate;
a shading part arranged below the active region and made from an electrically conductive material; and
a storage capacitor comprising a first plate and a second plate which are spaced apart and arranged oppositely;
wherein the first plate is arranged in a same layer as the shading part, and the second plate is arranged in a same layer as any one of the active region, the source/drain and the gate.

2. The array substrate of claim 1,
wherein the second plate is arranged in a same layer as the source/drain or the gate.

3. The array substrate of claim 1, wherein the storage capacitor further comprises:
a third plate electrically connected with the first plate, wherein the second plate is arranged between the first plate and the third plate, and the second plate and the third plate are arranged in a same layer as two layers among the gate, the source/drain and the active region respectively.

4. The array substrate of claim 3,
wherein the shading part, a buffer layer, the active region, a gate insulating layer, the gate, an interlayer insulating layer and the source/drain are arranged sequentially in a direction away from a base plate of the array substrate;
the second plate is arranged in a same layer as the gate; and
the third plate is arranged in a same layer as the source/drain.

5. The array substrate of claim 4, wherein
at least one insulating layer is arranged between a layer in which the shading part is arranged and a layer in which the second plate is arranged; and
the at least one insulating layer has a thickness t1 over the first plate and a thickness t2 over the shading part, wherein 0≤t1≤t2.

6. The array substrate of claim 5, wherein
the at least one insulating layer is a buffer layer covering the shading part; and
the active region is arranged over the buffer layer.

7. The array substrate of claim 6, wherein
the third plate is electrically connected with the first plate via a via hole which runs through the buffer layer, the gate insulating layer and the interlayer insulating layer.

8. The array substrate of claim 1, wherein
the active region is made from low temperature polycrystalline silicon.

9. The array substrate of claim 1, wherein
the array substrate comprises a gate driver circuit at a peripheral region, and the storage capacitor is a storage capacitor in the gate driver circuit.

10. A display device, comprising
an array substrate, wherein the array substrate comprises:
a thin film transistor comprising an active region, a source/drain and a gate;
a shading part arranged below the active region and made from an electrically conductive material; and
a storage capacitor comprising a first plate and a second plate which are spaced apart and arranged oppositely;
wherein the first plate is arranged in a same layer as the shading part, and the second plate is arranged in a same layer as any one of the active region, the source/drain and the gate.

11. A method for fabricating an array substrate, wherein
the array substrate comprises: a thin film transistor comprising an active region, a source/drain and a gate; a shading part arranged below the active region and made from an electrically conductive material; and a storage capacitor comprising a first plate and a second plate which are spaced apart and arranged oppositely,
wherein the first plate is arranged in a same layer as the shading part, and the second plate is arranged in a same layer as any one of the active region, the source/drain and the gate,
the method comprises steps of:
S1, forming a pattern comprising the first plate and the shading part by a first patterning process; and
S2, forming a pattern of the second plate by a second patterning process, and simultaneously forming a pattern of any of the active region, the source/drain and the gate.

12. The method of claim 11, wherein after the step S1 and prior to the step S2, the method further comprises:
step S102, forming a buffer layer on the pattern comprising the first plate and the shading part.

13. The method of claim 12, wherein after the step S102, the method further comprises:
step 103, forming the active region on the base plate from the step S102 by a third patterning process.

14. The method of claim 13, wherein after the step S103, the method further comprises:
step S104, on the base plate from the step S103, thinning the buffer layer at a region other than a region to which the shading part corresponds by etching.

15. The method of claim 12, wherein after the step S102, the method further comprises:
step S104′, forming the active region on the base plate from the step S102 by a third patterning process, and simultaneously thinning the buffer layer at a region other than a region to which the shading part corresponds.

16. The method of claim 14, wherein after the step S104, the method further comprises:
step S105, forming a gate over the active region and a second plate which is arranged oppositely to the first plate on the base plate from the step S104 by a fourth patterning process.

17. The method of claim 16, wherein after the step S105, the method further comprises:
step S106, forming an interlayer insulating layer on the base plate from the step S105; forming a first via hole which runs through the interlayer insulating layer and the gate insulating layer and a second via hole which runs through the interlayer insulating layer, the gate insulating layer and the buffer layer by a fifth patterning process; and forming the source/drain which is electrically connected with the active region through the first via hole and a third plate which is electrically connected with the first plate through the second via hole by a sixth patterning process.

18. The method of claim 15, wherein after the step S104′, the method further comprises:
step S105, forming a gate over the active region and a second plate which is arranged oppositely to the first plate on the base plate from the step S104′ by a fourth patterning process.

19. The display device of claim 10, wherein the second plate is arranged in a same layer as the source/drain or the gate.

20. The display device of claim 10, wherein the storage capacitor further comprises:
a third plate electrically connected with the first plate, wherein the second plate is arranged between the first plate and the third plate, and the second plate and the third plate are arranged in a same layer as two layers among the gate, the source/drain and the active region respectively.
